(19) United States
(12) Patent Application Publication
(10) Pub. No.: US 2012/0153303 A1
(43) Pub. Date: Jun. 21, 2012

(54) SEMICONDUCTOR ELEMENT AND METHOD FOR MANUFACTURING SAME

(75) Inventor: Masao Uchida, Osaka (JP)

(73) Assignee: PANASONIC CORPORATION, Osaka (JP)

(21) Appl. No.: 13/393,661

(22) PCT Filed: Aug. 31, 2010
(86) PCT No.: PCT/JP2010/005351

§ 371 Date: Mar. 1, 2012

(30) Foreign Application Priority Data
Sep. 2, 2009 (JP) 2009-202896

(51) Int. Cl. H01L 29/161; H01L 21/336

(52) U.S. Cl. 257/77; 438/268; 257/E29.084; 257/E21.41

(57) ABSTRACT

A semiconductor device 100 includes: a silicon carbide layer 102; a source region 104 of a first conductivity type disposed in the silicon carbide layer; a body region 103 of a second conductivity type disposed at a position in contact with the source region 104 in the silicon carbide layer; a contact region 105 of the second conductivity type formed in the body region; a drift region 102d of the first conductivity type disposed in the silicon carbide layer; and a source electrode 109 in ohmic contact with the source region 104 and the contact region 105, wherein: a side wall of the source electrode 109 is in contact with the source region 104; a lower surface of the source electrode 109 is in contact with the contact region 105 and is not in contact with the source region 104; and at least a portion of the source region 104 overlaps the contact region 105 as viewed from a direction perpendicular to a principle surface of a substrate 101.

### TECHNICAL FIELD

The present invention relates to a semiconductor device and a method for manufacturing the same.

### BACKGROUND ART

Silicon carbide (SiC) is a hard semiconductor material with a larger bandgap than silicon (Si), and it has been applied to various semiconductor devices such as power devices, hostile-environment devices, high-temperature devices, and high-frequency devices. Applications to power devices such as stitching devices and rectifier devices, among others, have been drawing public attention. Power devices using SiC have advantages such as the significant decrease in power loss as compared with Si power devices.

Of all power devices using SiC, typical switching devices include metal-insulator-semiconductor field effect transistors (MISFETs) and metal-semiconductor field effect transistors (MISFETs). Such a switching device can be switched, by way of a voltage applied to the gate electrode, between an ON state where a drain current of several A (amperes) or more, and an OFF state where the drain current is zero. Also, using SiC, it is possible to realize a high withstand voltage of several hundreds of V or more in the OFF state.

A structure of a switching device using SiC is proposed in Patent Document No. 1, for example. The structure of a conventional vertical metal-oxide-semiconductor field effect transistor (MOSFET) will now be described with reference to the drawings.

FIG. 15 is a schematic cross-sectional view showing a conventional vertical MOSFET using SiC in which two unit cells are arranged in parallel, for example. A vertical MOSFET typically includes a plurality of unit cells 1000.

A unit cell 1000 of a vertical MOSFET includes a silicon carbide epitaxial layer (semiconductor layer or drift layer) 102 formed on the principle surface of a low-resistance n-type SiC substrate 101, a channel layer 106 formed on the silicon carbide epitaxial layer 102, a gate electrode 108 provided on the channel layer 106 with a gate insulating film 107 interposed therebetween, a source electrode 1009 in contact with the surface of the silicon carbide epitaxial layer 102, and a drain electrode 110 provided on the reverse surface of the SiC substrate 101.

The silicon carbide epitaxial layer 102 includes a body region 103 having a conductivity type (herein, the p type) different from that of the SiC substrate 101, and a drift region 102d that is formed by a portion of the silicon carbide epitaxial layer 102 where the body region 103 is absent. The drift region 102d includes a junction field effect transistor (JFET) region 102j located between adjacent body regions 103. The silicon carbide epitaxial layer 102 is, for example, an n⁻-type silicon carbide layer containing an n-type impurity at a lower concentration than the SiC substrate 101. An n⁺-type source region 104 containing an n-type impurity at a high concentration and a p⁺-type contact region 1005 containing a p-type impurity at a higher concentration than the body region 103 are formed inside the body region 103. The body region 103, the source region 104 and the contact region 1005 are formed by a step of implanting the silicon carbide epitaxial layer 102 with an impurity, and a step of a high-temperature anneal (activation anneal) for activating the impurity implanted in the silicon carbide epitaxial layer 102.

The source region 104 and the drift region 102d are connected to each other via the channel layer 106. The channel layer 106 is, for example, a 4H—SiC layer formed on the silicon carbide epitaxial layer 102 by epitaxial growth. The contact region 1005 and the source region 104 each form an ohmic contact with the source electrode 1009. Thus, the body region 103 is electrically connected to the source electrode 1009 via the contact region 1005.

The source electrode 1009 can be formed by forming a conductive material (Ni) layer, for example, over the source region 104 of the silicon carbide epitaxial layer 102 and the contact region 1005, and then subjecting the conductive material (Ni) layer to a heat treatment at a high temperature.

The gate insulating film 107 is a thermally oxidized film (SiO₂ film) formed by thermal oxidization of the surface of the channel layer 106, for example. The gate electrode 108 is formed by using a conductive polysilicon, for example.

The gate electrode 108 is covered by an interlayer insulating film 111. An opening 111c is formed in the interlayer insulating film 111, and the source electrode 1009 in each unit cell is connected in parallel to an upper connection electrode (e.g., an Al electrode) 112 via the opening 111c. The drain electrode 110 may further include a reverse surface connection electrode 113.

In a MOSFET including the unit cell 1000 having a configuration shown in FIG. 15, a current can be conducted to the channel layer 106 lying under the gate electrode 108 with the gate insulating film 107 interposed therebetween, by way of a voltage applied to the gate electrode 108. Thus, a current (drain current) from the drain electrode 110 flows to the source electrode 1009 via the SiC substrate 101, the drift region 102d, the JFET region 102j, the channel layer 106 and the source region 104 (ON state).

### CITATION LIST

### Patent Literature

Patent Document No. 1: Japanese Laid-Open Patent Publication No. 2009-16530
Patent Document No. 2: Japanese Laid-Open Patent Publication No. 2000-216380

### SUMMARY OF INVENTION

### Technical Problem

While such a MOSFET as shown in FIG. 15 is often incorporated into an electric circuit such as an inverter or a converter, such an electric circuit with a built-in coil, or the like, has an induced current upon switching. Thus, when the MOSFET switches from the ON state to the OFF state, the induced current flows instantaneously between the upper connection electrode 112 and the drain electrode 110, accumulating a charge in the vicinity of the pn junction formed by the body region 103 and the drift region 102d. Then, if the contact resistance between the source electrode 1009 and the contact region 1005 is large, or the resistance of the p-type body region 103 is large, a potential difference may be produced in the body region 103, thereby turning ON the parasitic bipolar transistor formed by the source region 104, the body region 103 and the drift region 102d. As a result, the switching characteristic may be deteriorated (slowed down) because a transient current flows through the parasitic bipolar transistor even though the MOSFET is in the OFF state.

This problem will be described in detail with reference to FIG. 16.

FIG. 16(a) is a diagram illustrating an equivalent circuit which is a simplification of the unit cell 1000 shown in FIG. 15. BT1 is the parasitic bipolar transistor formed by the source region 104, the body region 103 and the drift region 102d. BD1 is the pn junction diode formed by the p-type body region 103 and the drift region 102d. Herein, a capacitor symbol is provided to depict the reverse direction of the pn junction. R1 is the resistance in the vertical direction (the direction perpendicular to the substrate surface) and R2 is the resistance in the horizontal direction (the direction parallel to the substrate surface) of the p⁺-type contact region 1005 and the p-type body region 103. MT1 is an actual transistor in the channel portion of the unit cell 1000. For the sake of simplicity, other components such as the drift resistance are not shown.

FIG. 16(b) is the equivalent circuit shown in FIG. 16(a), reproduced in a simpler fashion. When the transistor MT1 switches from the ON state to the OFF state, a transient current charges the diode (equivalent to a capacitor in this case) BD1. Then, a current also flows instantaneously through the resistors R1 and R2, and a potential that is positive with respect to the source S is produced at the point P1 (a point at which the resistors R1 and R2, the diode BD1 and the parasitic bipolar transistor BT1 are connected with one another). If the resistances R1 and R2 are high, the parasitic bipolar transistor BT1 is ON, and a current flows instantaneously through the parasitic bipolar transistor BT1. As a result, a portion of the induced current flows instantaneously in the vicinity of the channel layer 106. Therefore, it may not be possible to instantaneously turn OFF the transistor MT1, which is supposed to serve as a switch, thereby deteriorating (slowing down) the switching characteristic.

Particularly, with the p-type body region 103 formed by silicon carbide, as compared with a case where it is formed by Si, the resistance R2 in the horizontal direction is higher, and therefore the parasitic bipolar transistor BT1 is more easily turned ON. As compared with Si, silicon carbide has a greater bandgap energy and the impurity level (acceptor level) of boron, aluminum, or the like, which serves as an acceptor, is deep, and silicon carbide therefore produces fewer carriers. Therefore, in the MOSFET operating temperature range, the carrier concentration is significantly smaller than the dopant concentration in the p-type body region 103, thereby resulting in a high sheet resistance.

In contrast, by increasing the impurity concentration across the entire p-type body region 103, the sheet resistance of the p-type body region can be reduced. However, the following problems occur when the impurity concentration of the p-type body region 103 is increased.

A MOSFET normally has a structure in which a plurality of unit cells are arranged with one another. A current (drift current) of the MOSFET flows through the JFET region 102j between adjacent p-type body regions 103. Now, if the impurity concentration of the p-type body region 103 is increased, a depletion layer expands more easily in the drift region 102d at the pn junction between the p-type body region 103 and the drift region 102d. This increases the resistance of the JFET region 102j, and increases the ON resistance of the MOSFET.

Thus, with a conventional MOSFET, it is difficult to suppress the decrease in device characteristics due to the parasitic bipolar transistor BT1, without increasing the ON resistance.

The present invention has been made in view of the above, and an object thereof is to provide semiconductor device using silicon carbide, with which the switching speed is prevented from being slowed down as the parasitic bipolar transistor is turned ON instantaneously, without increasing the ON resistance.

### Solution to Problem

A semiconductor device of the present invention includes: a substrate; a silicon carbide layer disposed on the substrate; a source region of a first conductivity type disposed in the silicon carbide layer; a body region of a second conductivity type disposed at a position in contact with the source region in the silicon carbide layer; a contact region of the second conductivity type disposed in the body region and electrically connected to the body region; a drift region of the first conductivity type disposed in a region of the silicon carbide layer excluding the source region, the body region and the contact region; and a source electrode in ohmic contact with the source region and the contact region, wherein: a side wall of the source electrode is in contact with the source region; a lower surface of the source electrode is in contact with the contact region and is not in contact with the source region; and at least a portion of the source region overlaps the contact region as viewed from a direction perpendicular to a principle surface of the substrate.

In a preferred embodiment, the source electrode is formed by a metal silicide layer.

In a preferred embodiment, the lower surface of the source electrode is located within the contact region as viewed from the direction perpendicular to the principle surface of the substrate.

In a preferred embodiment, substantially an entirety of the lower surface of the source electrode is in contact with the contact region.

In a preferred embodiment, a thickness of the source electrode is greater than a thickness of the source region.

In a preferred embodiment, at least a portion of the contact region is disposed at a position deeper than a lower end of the source region in the silicon carbide layer.

In a preferred embodiment, a contour of the contact region generally coincides with a contour of the source region as viewed from the direction perpendicular to the principle surface of the substrate.

In a preferred embodiment, the body region is formed in a surface region of the silicon carbide layer so as surround the source region, the semiconductor device further including: a gate insulating film covering a portion of the silicon carbide layer; a gate electrode insulated from the silicon carbide layer by the gate insulating film; an upper connection electrode electrically connected to the source electrode; and a drain electrode provided on a reverse surface of the substrate.

In a preferred embodiment, the body region is disposed under the source region in contact with the source region, the semiconductor device further including: a trench passing through the source region and the body region to reach the drift region; a gate insulating film disposed in the trench so as to cover a side surface of the body region; a gate electrode insulated from the silicon carbide layer by the gate insulating film; an upper connection electrode electrically connected to the source electrode; and a drain electrode provided on a reverse surface of the substrate.

In a preferred embodiment, the semiconductor device further includes a channel layer of the first conductivity type disposed between the gate insulating film and the silicon carbide layer, wherein the channel layer is in contact with the source region.

In a preferred embodiment, the source region contains an impurity element imparting the first conductivity type; and the source electrode contains carbon and the same element as the impurity element.

In a preferred embodiment, on a cross section that is parallel to the principle surface of the substrate and that includes the contact region and the body region, a percentage of area of the contact region with respect to the body region is 20% or more and 80% or less.

A method for manufacturing a semiconductor device of the present invention includes: a silicon carbide layer formation step of forming a silicon carbide layer including a source region of a first conductivity type, a body region of a second conductivity type in contact with the source region, a contact region of the second conductivity type disposed in the body region and electrically connected to the body region, and a drift region of the first conductivity type disposed in a region of the silicon carbide layer excluding the body region, the source region and the contact region; a source electrode formation step of forming a source electrode in ohmic contact with the source region and the contact region, wherein a side wall of the source electrode is in contact with the source region, and a lower surface of the source electrode is in contact with the contact region and is not in contact with the source region, wherein after the source electrode is formed, at least a portion of the source region overlaps the contact region as viewed from a direction perpendicular to a principle surface of the substrate.

In a preferred embodiment, the source electrode formation step includes the steps of: (a1) etching a portion of the silicon carbide layer so as to expose a side wall of the source region; (a2) forming a metal layer so as to be in contact with the exposed side wall of the source region; and (a3) performing a heat treatment so as to diffuse a metal contained in the metal layer into the source region and the contact region and react the metal and silicon carbide with each other, thereby forming the source electrode formed by a metal silicide.

In a preferred embodiment, the source electrode formation step includes the steps of: (b1) forming a metal layer on a portion of the source region; and (b2) performing a heat treatment so as to diffuse a metal contained in the metal layer into the source region and the contact region and react the metal and silicon carbide with each other, thereby forming the source electrode formed by a metal silicide.

In a preferred embodiment, the method for manufacturing a semiconductor device further includes the step of: forming, on the silicon carbide layer, a channel layer that is in contact with the source region and is formed by silicon carbide of the first conductivity type, prior to the source electrode formation step, wherein: the step (b1) is a step of forming the metal layer on the channel layer; and in the step (b2), the metal is diffused into the channel layer, the source region and the contact region so as to react the metal and silicon carbide with each other.

In a preferred embodiment, the silicon carbide layer formation step includes the steps of: preparing a substrate with a silicon carbide layer of the first conductivity type formed on a surface thereof; implanting an impurity of the second conductivity type into the silicon carbide layer of the first conductivity type using a first implantation mask, thereby forming the body region; implanting an impurity of the first conductivity type into the silicon carbide layer of the first conductivity type using a second implantation mask, thereby forming the source region; and implanting an impurity of the second conductivity type into the body region using a third implantation mask, thereby forming the contact region.

In a preferred embodiment, the third implantation mask is the same as the second implantation mask.

### Advantageous Effects of Invention

With the present invention, the contact area between the source electrode and the p⁺-type contact region can be made larger as compared with conventional techniques, without substantially increasing the contact resistance between the source region and the source electrode, and it is therefore possible to reduce the contact resistance between the source electrode and the p⁺-type contact region. Therefore, it is possible to prevent the switching speed from being slowed down as the parasitic bipolar transistor is turned ON instantaneously, without increasing the ON resistance.

With the present invention, since the lower surface of the source electrode is not in contact with the n⁺-type source region, it is possible to accordingly reduce the size of the unit cell and to increase the density with which unit cells are loaded.

Moreover, with the present invention, it is possible to manufacture such semiconductor devices as described above without complicating the manufacturing processes.

### BRIEF DESCRIPTION OF DRAWINGS

FIG. 1 (a) to (c) are schematic diagrams illustrating a semiconductor device according to a first embodiment of the present invention, wherein (a) is a schematic cross-sectional view of a unit cell of the semiconductor device, (b) is a schematic plan view showing a silicon carbide layer surface of a unit cell, and (c) is a plan view illustrating an arrangement of a plurality of unit cells in the semiconductor device.

FIG. 2 A plan view illustrating an arrangement of unit cells of another semiconductor device of the first embodiment.

FIG. 3 (a) to (h) are step-by-step cross-sectional views illustrating a method for manufacturing a semiconductor device according to the first embodiment of the present invention.

FIG. 4 (a) to (e) are step-by-step cross-sectional views illustrating the method for manufacturing a semiconductor device according to the first embodiment of the present invention.

FIG. 5 A graph showing a depth-direction concentration profile of an impurity-implanted layer across a cross section along line A-A′ of the semiconductor device shown in FIG. 3(d).

FIG. 6 A graph showing a depth-direction concentration profile of the impurity-implanted layer across a cross section along line B-B′ of the semiconductor device shown in FIG. 3(d).

FIG. 7 A graph showing a depth-direction concentration profile of the impurity-implanted layer across a cross section along line C-C′ of the semiconductor device shown in FIG. 3(d).

FIG. 8 (a) to (c) are schematic diagrams illustrating a semiconductor device according to a second embodiment of the present invention, wherein (a) is a schematic cross-sectional view of a unit cell of the semiconductor device, (b) is a schematic plan view showing a silicon carbide layer surface of a unit cell, and (c) is a plan view illustrating an arrangement of a plurality of unit cells in the semiconductor device.

FIG. 9 (a) to (g) are step-by-step cross-sectional views illustrating a method for manufacturing a semiconductor device according to the second embodiment of the present invention.

FIG. 10 (a) to (e) are step-by-step cross-sectional views illustrating the method for manufacturing a semiconductor device according to the second embodiment of the present invention.

FIG. 11 A schematic cross-sectional view of another semiconductor device according to an embodiment of the present invention.

FIG. 12 A schematic cross-sectional view of still another semiconductor device according to an embodiment of the present invention.

FIG. 13 A schematic cross-sectional view of still another semiconductor device according to an embodiment of the present invention.

FIG. 14 A schematic cross-sectional view of still another semiconductor device according to an embodiment of the present invention.

FIG. 15 A schematic cross-sectional view illustrating a unit cell of a conventional vertical MOSFET using SiC.

FIG. 16 (a) is a diagram illustrating a cross-sectional view of the unit cell shown in FIG. 15 and an equivalent circuit thereof, and (b) is a diagram showing an equivalent circuit of the unit cell.

### DESCRIPTION OF EMBODIMENTS

### First Embodiment

A first embodiment of the semiconductor device of the present invention will now be described with reference to the drawings. A semiconductor device of the present embodiment is a vertical MOSFET using silicon carbide.

The semiconductor device of the present embodiment is formed by unit cells, each including a silicon carbide layer, a source electrode and a drain electrode electrically connected to the silicon carbide layer, and a gate electrode used for switching the semiconductor device between the ON state and the OFF state, and typically has a structure with a plurality of unit cells arranged therein.

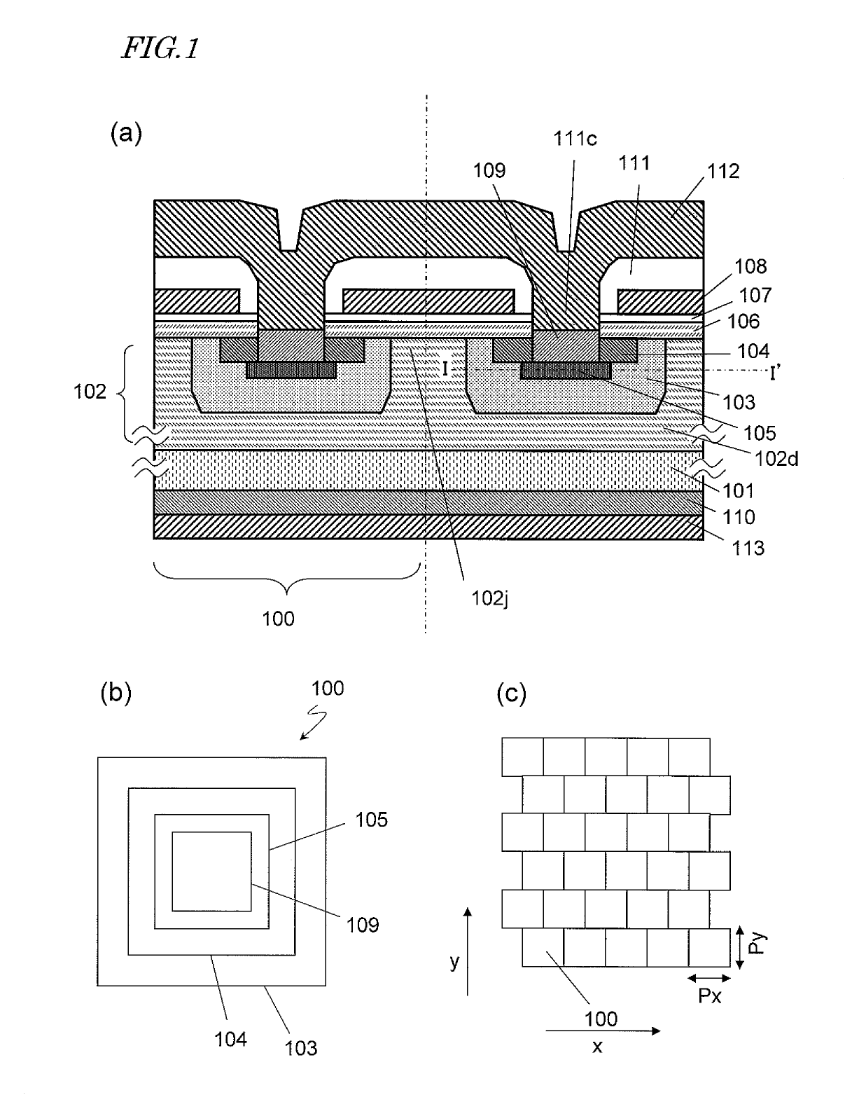

FIG. 1(a) is a schematic cross-sectional view of unit cells of the present embodiment, showing adjacent two unit cells. FIG. 1(b) is a schematic plan view showing the surface of the silicon carbide layer of a unit cell. FIG. 1(c) is a plan view illustrating an arrangement of a plurality of unit cells.

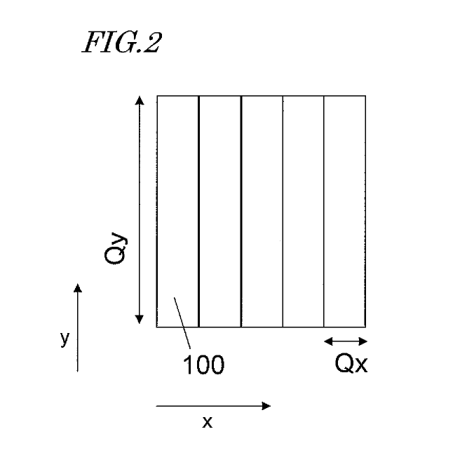

In the example shown in FIG. 1, unit cells 100 have a generally rectangular (or square) planar shape, and are arranged two-dimensionally in the x direction and in the y direction perpendicular to the x direction. The unit cells 100 may have a strip-shaped planar shape extending in one direction (e.g., the y direction) as shown in FIG. 2, for example. The repeating units of the unit cells in the x direction and the y direction (the lengths of the unit cells along the x and y directions) are denoted as Px and Py in FIG. 1(b), and the repeating units of the unit cells in the x direction and the y direction are denoted as Qx and Qy in FIG. 2. Px, Py and Qx are 5 to 20 μm, preferably 8 to 15 μm. Qy is greater than Px, Py and Qx, and is 20 μm or more. At maximum, Qy may be a length (e.g., 5 mm) corresponding to one side of the chip size of the semiconductor device, which is formed by a collection of the unit cells.

The unit cell 100 includes a substrate 101, a silicon carbide layer 102 formed on the surface of the substrate 101, a source electrode 109 electrically connected to the silicon carbide layer 102, a gate electrode 108 covering at least a portion of the silicon carbide layer 102, and a drain electrode 110 electrically connected to the reverse surface of the substrate 101. The channel layer 106 and the gate insulating film 107 are formed in this order between the silicon carbide layer 102 and the gate electrode 108.

The substrate 101 is an n-type semiconductor substrate formed by silicon carbide, e.g., is formed by 4H—SiC, and is an off-cut substrate having a surface on which the step density is increased by inclining the surface by several degrees (the off angle) off of the (0001) Si plane.

The silicon carbide layer 102 includes the source region 104 of a first conductivity type (herein, the n type) disposed in a surface region of the silicon carbide layer 102, and the body region 103 of a second conductivity type (herein, the p type) disposed at a position in contact with the n⁺-type source region 104. A p⁺-type contact region 105 electrically connected to the p-type body region 103 is disposed in the p-type body region 103. A region of the silicon carbide layer 102 where none of the n⁺-type source region 104, the p-type body region 103 and the p⁺-type contact region 105 is present includes the drift region 102d of the first conductivity type (the n type).

In the present embodiment, the silicon carbide layer 102 is a silicon carbide epitaxial layer formed on the substrate 101, for example. The p-type body regions 103 of different unit cells are formed spaced apart from each other in the silicon carbide layer 102. The n-type drift region 102d is formed by a portion of the silicon carbide layer 102 where the p-type body region 103 is not formed. The drift region 102d includes the JFET region 102j located between the body regions 103 of adjacent unit cells. The drift region 102d is, for example, an n⁻-type silicon carbide layer containing an n-type impurity at a lower concentration than the substrate 101. The n⁺-type source region 104 containing an n-type impurity at a high concentration and the p⁺-type contact region 105 containing a p-type impurity at a higher concentration than the p-type body region 103 are formed in the p-type body region 103. In the unit cell 100 illustrated in FIG. 1, the p-type body region 103 is formed so as to surround the n⁺-type source region 104 at the surface of the silicon carbide layer 102. The p⁺-type contact region 105 is formed at a position deeper than the n⁺-type source region 104. That is, at least a portion of the p⁺-type contact region 105 is formed at a position deeper than the lower end (lowermost portion) of the n⁺-type source region 104.

The source electrode 109 is in ohmic contact with the n⁺-type source region 104 and the p⁺-type contact region 105. The source electrode 109 is formed by a metal silicide layer, for example. In the present embodiment, the side wall of the source electrode 109 is in contact with the n⁺-type source region 104. The lower surface (lower end) of the source electrode 109 is in contact with the p⁺-type contact region 105, but is not in contact with the n⁺-type source region 104. At least a portion of the n⁺-type source region 104 overlaps the p⁺-type contact region 105 present at a position deeper than the n⁺-type source region 104, as viewed from a direction perpendicular to the principle surface of the substrate 101.

The channel layer 106 is an n-type epitaxial layer formed by 4H—SiC, for example, and is provided so as to connect adjacent p-type body regions 103 together and to be in contact with the n⁺-type source region 104.

The source electrodes 109 of different unit cells are connected in parallel to one another by the upper connection electrode 112. The upper connection electrode 112 and the gate electrode 108 are electrically separated from each other by the interlayer insulating film 111. The drain electrode 110 formed on the reverse surface of the substrate 101 is in ohmic contact with the substrate 101. The reverse surface connection electrode 113 is provided on the drain electrode 110.

The unit cells 100 are arranged two-dimensionally as shown in FIGS. 1(c) and 2, and wiring pads and peripheral terminal structures are added as necessary, thereby forming a vertical MISFET.

With the present embodiment, the contact area between the source electrode 109 and the p⁺-type contact region 105 can be made larger as compared with conventional techniques, and it is therefore possible to reduce the contact resistance between the source electrode 109 and the p⁺-type contact region 105.

Since the n⁺-type source region 104 is in contact with the side wall of the source electrode 109, it is possible to obtain the advantageous effects described above without significantly increasing the ON resistance. Moreover, since the lower surface of the source electrode 109 is not in contact with the n⁺-type source region 104, it is possible to accordingly reduce the size of the unit cell and to increase the density with which unit cells are loaded.

With the conventional structure shown in FIG. 15, the lower surface of the source electrode 1009 needs to be in contact not only with the p⁺-type contact region 1005 but also with the n⁺-type source region 104. In contrast, with the semiconductor device of the present embodiment shown in FIG. 1, the lower surface of the source electrode 109 is not in contact with the n⁺-type source region 104. Therefore, the p⁺-type contact region 105 can be formed to be larger as compared with the conventional structure (FIG. 15). For example, on the cross section taken along line I-I′ shown in FIG. 1, i.e., a cross section that is parallel to the principle surface of the SiC substrate 101 and that includes the p⁺-type contact region 105 and the p-type body region 103 in contact with the p⁺-type contact region 105, the percentage of area of the p⁺-type contact region 105 with respect to the p-type body region 103 (hereinafter referred to as the “contact region area percentage”.) can be increased to 20% or more. In a specific example where each side of the body region 103 is 6.6 μm and each side of the source electrode 109 is 3 μm, the area of the p⁺-type contact region of the conventional technique was ½, for example, of the area (conductive surface) of the source electrode 109, and the area percentage of the contact region was about 10%. In contrast, with the present embodiment, since the area of the p⁺-type contact region 105 can be made greater than or equal to the area of the source electrode 109, the area percentage of the contact region is 20% or more. With the second embodiment to be described later, the area percentage of the contact region can be increased to be substantially equal to the percentage of area of the n⁺-type source region 104 with respect to the body region 103 (e.g., 80%).

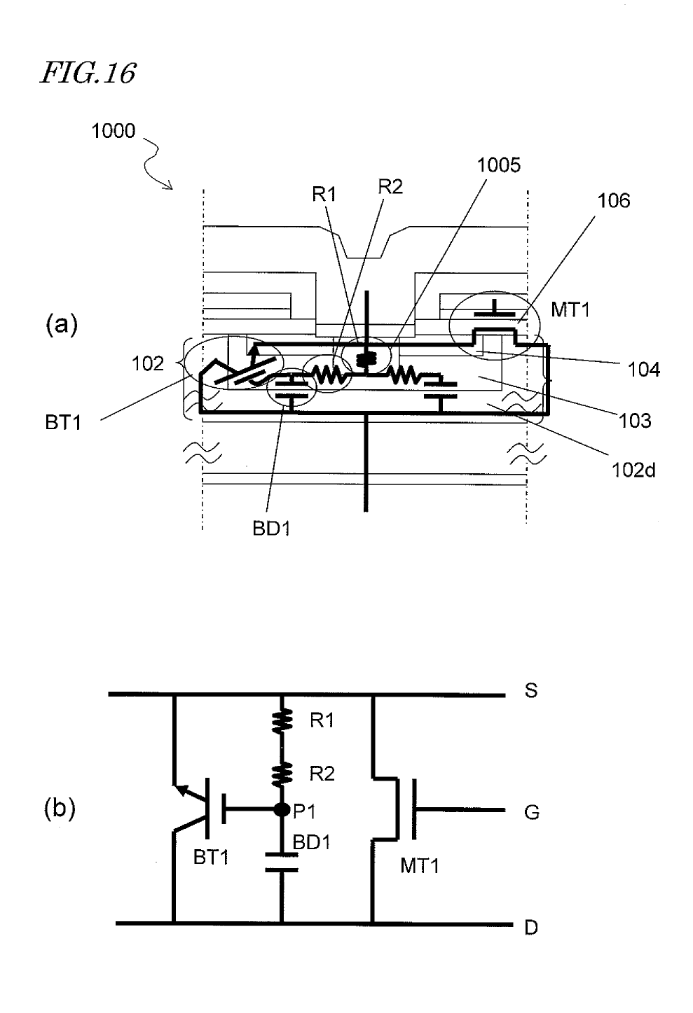

Thus, since the area percentage of the contact region can be increased as compared with the conventional technique, the resistance R2 shown in FIG. 16 can be reduced from that of the conventional technique. In the present embodiment, the p⁺-type contact region 105 is disposed under the n⁺-type source region 104 so as to overlap the n⁺-type source region 104 as viewed from a direction perpendicular to the principle surface of the substrate 101. Therefore, it is possible to further suppress the resistance R2 in the horizontal direction of the body region 103. As a result, it is possible to prevent the parasitic bipolar transistor from being turned ON, and it is therefore possible to prevent the switching speed from being slowed down.

While it is only necessary that at least a portion of the lower surface (lower end) of the source electrode 109 is in contact with the p⁺-type contact region 105 in each unit cell 100, substantially the entirety of the lower surface of the source electrode 109 is preferably in contact with the p⁺-type contact region 105 as shown in the figure. Then, it is possible to more effectively increase the contact area between the source electrode 109 and the p⁺-type contact region 105. As a result, it is possible to further suppress the contact resistance, and it is therefore possible to more effectively increase the switching characteristic.

In the illustrated example, the lower surface of the source electrode 109 is located within the p⁺-type contact region 105 as viewed from above the silicon carbide layer 102 (from a direction perpendicular to the principle surface of the substrate 101). Thus, substantially the entirety of the lower surface of the source electrode 109 can be brought into contact with the p⁺-type contact region 105.

The width of the p⁺-type contact region 105 is preferably greater than the width of the source electrode 109 on any cross section perpendicular to the principle surface of the substrate 101. Then, substantially the entirety of the lower surface of the source electrode 109 can be more easily brought into contact with the p⁺-type contact region 105.

While the width of the p⁺-type contact region 105 is smaller than the width of the n⁺-type source region 104 on a cross section perpendicular to the principle surface of the substrate 101 in the unit cell 100, it may be equal to the width of the n⁺-type source region 104. Note however that the width of the p⁺-type contact region 105 is set to be smaller than the width of the body region 103 on any cross section perpendicular to the principle surface of the substrate 101 so that the p⁺-type contact region 105 is disposed within the body region 103 (i.e., so that the p⁺-type contact region 105 is surrounded by the body region 103 as viewed from above the substrate 101).

While the contour of the p⁺-type contact region 105 is located within the contour of the n⁺-type source region 104 as viewed from above the silicon carbide layer 102 in the unit cell 100, it may coincide with the contour of the n⁺-type source region 104 as in an embodiment to be described below.

The contact region preferably has such a cross section that the cross-sectional area of the cross section of the contact region that is parallel to the surface of the substrate is greater than the maximum value of the cross-sectional area of the cross section of the source electrode that is parallel to the surface of the substrate. In the present embodiment, the cross-sectional area of the cross section of the p⁺ contact region 105 that is parallel to the surface of the substrate 101 is greater than the cross-sectional area of the cross section of the source electrode 109 that is parallel to the surface of the substrate 101. Therefore, even if there is a misalignment in the mask alignment in a process to be described below, the entire lower surface of the source electrode 109 can be more reliably brought into contact with the p⁺-type contact region 105, and it is therefore possible to more effective reduce the contact resistance therebetween.

The contact surface at which the lower surface of the source electrode 109 and the p⁺-type contact region 105 contact with each other in the present embodiment may be generally parallel to the principle surface of the SiC substrate 101. In this case, the area of the p⁺-type contact region 105 is preferably greater than the area of the source electrode 109 on the cross section including the contact surface.

In order to contact the source region 104 on its side wall and contact the p⁺-type contact region 105 on its lower surface, the source electrode 109 preferably passes through the n⁺-type source region 104 to be in contact with the p⁺-type contact region 105. In order to more reliably obtain such a structure, the source electrode 109 is preferably thicker than the n⁺-type source region 104.

The semiconductor device shown in FIG. 1 can be produced by a method described below, for example.

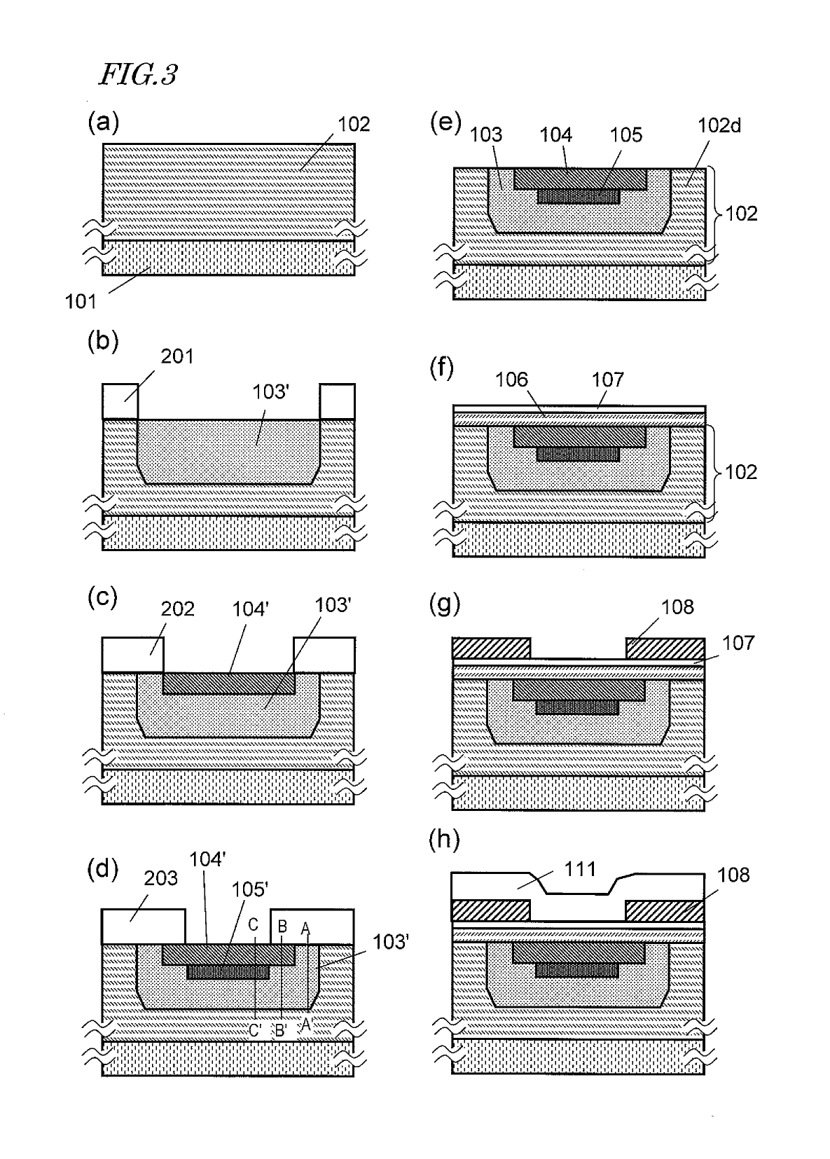

First, as shown in FIG. 3(a), the silicon carbide layer 102 is formed on the substrate 101 formed by silicon carbide. For example, a 4H—SiC substrate having a diameter of 3 inches whose principle surface has an off angle of 8 degrees off of (0001) in the [11-20] (112bar0) direction is used as the substrate 101. The conductivity type of the substrate 101 is the n type, and the carrier concentration is about 7×10¹⁸ cm⁻³, for example.

The silicon carbide layer 102 can be formed by a CVD method using a heating furnace. Herein, a silicon carbide layer doped with an n-type is epitaxially grown on the principle surface of the substrate 101. While the thickness of the silicon carbide layer 102 varies depending on the specifications required of the semiconductor device, it is adjusted in the range of 5 to 100 μm, for example. The impurity concentration of the silicon carbide layer 102 is appropriately adjusted in the range of 1×10¹⁴ to 1×10¹⁷ cm⁻³. A buffer layer formed by n-type silicon carbide may be provided between the substrate 101 and the silicon carbide layer 102. The buffer layer has a thickness of 1 μm, for example, and an impurity concentration of 1×10¹⁸ cm⁻³, for example.

Next, as shown in FIG. 3(b), a first impurity ion implanted layer (thickness: 0.5 μm to 2 μm, for example) 103′ is formed in a selected region of the silicon carbide layer 102.

Specifically, first, a mask layer 201 formed by a silicon oxide film (SiO₂), for example, is formed on the surface of the silicon carbide layer 102. The mask layer 201 has an opening that defines a region of the silicon carbide layer 102 to be the first impurity ion implanted layer 103′. The mask layer 201 can be formed in any manner by photolithography and etching. Herein, the shape of the opening of the mask layer 201 is designed so that the surface shape of the first impurity ion implanted layer 103′ is a square shape (length of each side: 6.6 μm, for example). While the thickness of the mask layer 201 is determined based on the material thereof and the implantation conditions, it is preferably set to be sufficiently larger than the implantation range. Next, a p-type impurity ion (e.g., an Al ion) is implanted into the silicon carbide layer 102 from above the mask layer 201. The substrate temperature during the ion implantation may be adjusted in the range of room temperature to 1000° C., for example, or it may be a higher temperature. It is preferably 300° C. or more. Thus, the p-type first impurity ion implanted layer 103′ is formed in a region of the silicon carbide layer 102 where an impurity ion is implanted. A region of the silicon carbide layer 102 that remains not implanted with an impurity ion becomes the n-type drift region 102d.

Next, as shown in FIG. 3(c), a second impurity ion implanted layer (thickness: 0.2 μm to 1 μm, for example) 104′ is formed in the silicon carbide layer 102.

Specifically, first, a mask layer 202 with an opening through which a portion of the surface of the first impurity ion implanted layer 103′ is exposed is formed on the silicon carbide layer 102. The mask layer 202 may be formed by a similar method after the previous mask layer 201 is removed. Alternatively, an additional layer may be deposited on the mask layer 201, without removing the mask layer 201, and the entire surface may be subjected to anisotropic etching to form a sidewall on the side wall of the mask layer 201, thereby forming the mask layer 202 formed by the mask layer 201 and the sidewall (self-aligned process). Herein, the shape of the opening in the mask layer 202 is designed so that the surface of the second impurity ion implanted layer 104′ has a square shape (length of each side: 5.6 μm, for example). Next, an n-type impurity ion (e.g., a nitrogen ion or a phosphorus ion) is implanted into the silicon carbide layer 102 from above the mask layer 202. The substrate temperature during the ion implantation is similar to the substrate temperature during the p-type impurity ion implantation described above with reference to FIG. 3(b). After the ion implantation, the mask layer 202 is removed.

Then, as shown in FIG. 3(d), a third impurity ion implanted layer 105′ is formed in the silicon carbide layer 102. The third impurity ion implanted layer 105′ is formed by forming a mask layer 203 with an opening through which a portion of the second impurity ion implanted layer 104′ is exposed on the silicon carbide layer 102, and implanting a p-type impurity ion (e.g., an Al ion) into the silicon carbide layer 102 from above the mask layer 203.

In the present embodiment, the implantation conditions are controlled so that the third impurity ion implanted layer 105′ is formed under the second impurity ion implanted layer 104′. The substrate temperature during the ion implantation may be similar to the substrate temperature during the p-type impurity ion implantation described above with reference to FIG. 3(b). The second impurity ion implanted layer 104′ and the second impurity ion implanted layer 105′ may have some overlap at the interface therebetween. After the ion implantation, the mask layer 203 is removed.

Herein, with the use of the mask layer 203 with an opening through which a portion of the second impurity ion implanted layer 104′ is exposed, the third impurity ion implanted layer 105′ is formed within the contour of the second impurity ion implanted layer 104′ as viewed from above the substrate 101.

Then, as shown in FIG. 3(e), the first, second and third impurity ion implanted layers 103′, 104′ and 105′ are subjected to an activation anneal at a high temperature of 1500° C. or more, thereby forming the p-type body region 103, the n⁺-type source region 104 and the p⁺-type contact region 105, respectively. The impurity concentrations of the p-type body region 103 and the n⁺-type source region 104 obtained are determined by the conditions during the ion implantation described above, and are adjusted in the range of 1×10¹⁷ to 1×10¹⁹ cm⁻³ and in the range of 1×10¹⁸ to 1×10²¹ cm⁻³, respectively. The impurity concentration of the p⁺-type contact region 105 is adjusted so that it is higher than the impurity concentration of the p-type body region 103.

Then, as shown in FIG. 3(f), the channel layer 106 formed by n-type silicon carbide is epitaxially grown on the silicon carbide layer 102. The average impurity concentration of the channel layer 106 is adjusted to be in the range of 1×10¹⁵ to 1×10¹⁸ cm⁻³. The channel layer 106 may be a single layer or may have a layered structure. In the case of a layered structure, a so-called “delta-doped layer structure” may be employed, which includes alternating layers of delta-doped layers having a high impurity concentration (with a thickness of about 5 to 50 nm, and an impurity concentration of 1×10¹⁷ to 1×10¹⁹ cm⁻³, for example), and undoped layers (with a thickness of about 5 to 200 nm, and including low concentrations of an impurity concentration of 1×10¹⁶ cm⁻³ or less).

Then, the gate insulating film 107 is formed. The gate insulating film 107 can be formed by, for example, thermally oxidizing the surface of the channel layer 106 formed by silicon carbide at a temperature of 1000 to 1200° C. Alternatively, it may be formed by depositing a single-layer or multi-layer insulating film on the channel layer 106. The thickness of the gate insulating film 107 is adjusted in the range of 20 nm to 200 nm.

Next, as shown in FIG. 3(g), the gate electrode 108 is formed on the gate insulating film 107. The gate electrode 108 is formed by forming a polysilicon film, doped with phosphorus so as to decrease the resistance thereof, for example, or a metal film, on the gate insulating film 107, and then patterning the film in a desired shape. The thickness of the gate electrode 108 is 500 nm, for example. The gate electrode may have a layered structure of polysilicon and a metal layer (or a silicide layer).

Moreover, as shown in FIG. 3(h), the interlayer insulating film 111 is deposited so as to cover the patterned gate electrode 108. The interlayer insulating film is formed by SiO₂, for example, and the thickness is about 1 μm.

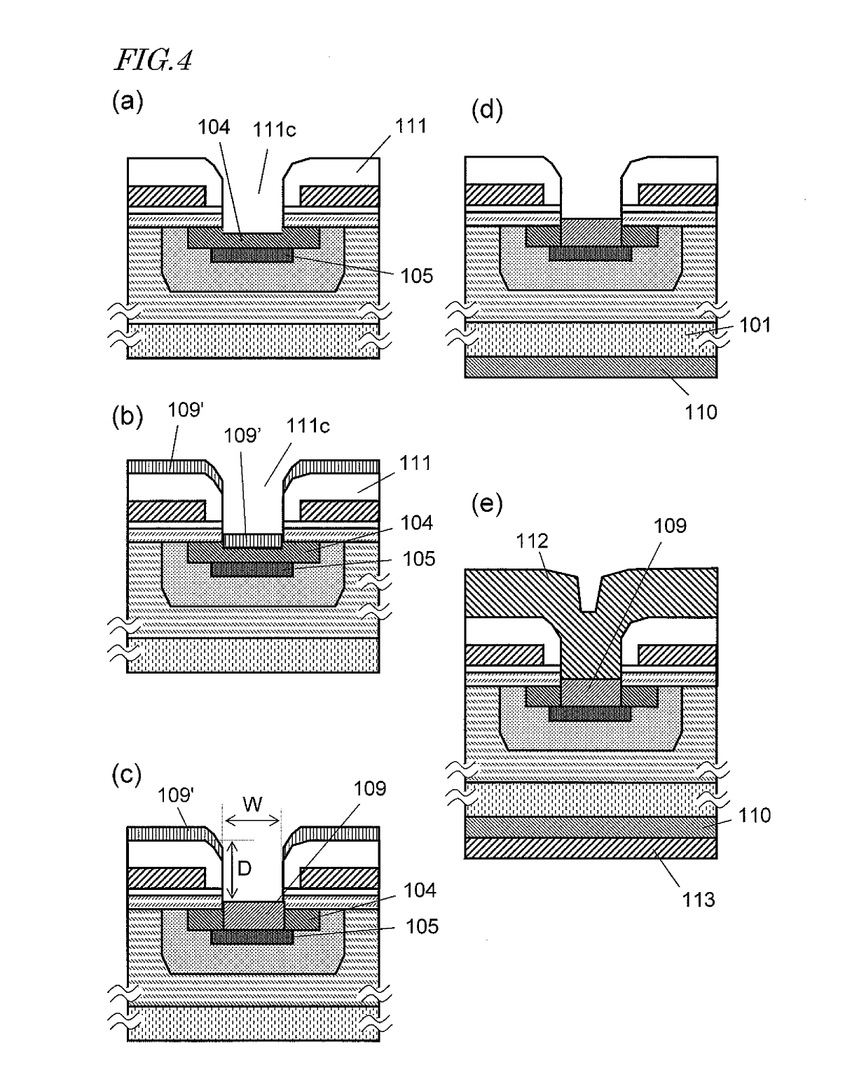

Next, as shown in FIG. 4(a), the opening 111c is formed by etching the interlayer insulating film 111. The opening 111c is disposed over a portion of the n⁺-type source region 104 that overlaps the p⁺-type contact region 105. Thus, in the source electrode formation step to be described below, the metal to be deposited in the opening 111c can be diffused into the p⁺-type contact region 105.

Specifically, a mask layer (not shown) with an opening (referred to as the “mask opening”.) is formed on the interlayer insulating film 111, for example. The width of the mask opening is preferably smaller than the width of the p⁺-type contact region 105, and is 3 μm, for example. Then, a portion of the interlayer insulating film 111 that is exposed through the mask opening is etched away by dry etching. Thus, the opening 111c through which a portion of the n⁺-type source region 104 is exposed is formed. In the present embodiment, not only the interlayer insulating film 111, but also the gate insulating film 107, the channel layer 106 and a surface portion of the n⁺-type source region 104, are etched away by dry etching. Thus, the surface of the n⁺-type source region 104 (including the side wall of the n⁺-type source region 104) is exposed through the opening 111c. Herein, as long as the surface of the n⁺-type source region 104 is exposed through the opening 111c, the surface portion of the n⁺-type source region 104 does not need to be etched away.

Alternatively, the opening 111c may be formed so as to pass through the interlayer insulating film 111 and the gate insulating film 107, exposing the upper surface of the channel layer 106. Alternatively, the n⁺-type source region 104 under the interlayer insulating film 111 may be removed so as to expose the side wall of the n⁺-type source region 104 and the p⁺-type contact region 105.

Next, as shown in FIG. 4(b), a metal layer 109′ (e.g., Ni) to be the source electrode is deposited on the interlayer insulating film 111 and in the opening 111c. Herein, the metal layer 109′ is in contact with the surface of the n⁺-type source region 104 (the side wall and the upper surface of the n⁺-type source region 104), which has been exposed through the etching step described above. Although not shown in the figures, the metal layer 109′ may be deposited also on the inner wall of the opening 111c of the interlayer insulating film 111.

Where the opening 111c is formed to reach the upper surface of the channel layer 106, and the n⁺-type source region 104 is not exposed in the opening 111c, the metal layer 109′ may be disposed to be in contact with the upper surface of the channel layer 106. Then, in a step to be described below, the metal layer deposited in the opening 111c can be reacted with the channel layer 106 and the underlying n⁺-type source region 104 so as to form a metal silicide to be the source electrode. If the n⁺-type source region 104 under the opening 111c is removed by etching, the metal layer 109′ may be disposed so as to be in contact with the exposed side wall of the n⁺-type source region 104 and the p⁺-type contact region 105. Then, in a step to be described below, the side wall of the n⁺-type source region 104 and the p⁺-type contact region 105 can be reacted with the metal layer deposited in the opening 111c so as to form the source electrode.

Then, as shown in FIG. 4(c), the metal layer 109′ deposited on the opening 111c of the interlayer insulating film 111 is subjected to a heat treatment at about 800 to 1000° C., for example. Thus, in the opening 111c, a portion of the metal layer 109′ that is in contact with silicon carbide (the source region 104 and the channel layer 106) reacts selectively, thereby forming the source electrode 109 formed by a metal silicide (herein, an Ni silicide). Therefore, in addition to the metal silicide, the source electrode 109 also contains carbon (C) and impurity elements imparting the n type, which were contained in the source region 104.

In the heat treatment described above, the metal contained in the metal layer 109′ is primarily diffused into, and silicified in, the n⁺-type source region 104. As a result, a metal silicide (source electrode) 109 is formed whose thickness is about twice that of the metal of the metal layer 109′ used in the reaction. Therefore, the lower surface of the source electrode 109 can be reliably brought into contact with the p⁺-type contact region 105 by selecting the amount of dry etching of the n⁺-type source region 104 shown in FIG. 4(a), the thickness of the metal layer 109′, and the heat treatment conditions.

It is preferred that the metal layer 109′ is thicker than the n⁺-type source region 104 after being etched in the step shown in FIG. 4(a), and that the heat treatment conditions are adjusted so that the metal layer 109′ reacts with silicon carbide across its thickness direction. Then, the metal of the metal layer 109′ diffuses into not only the n⁺-type source region 104 but also a surface portion of the p⁺-type contact region 105, thereby obtaining the source electrode 109, which is more reliably in ohmic contact with the p⁺-type contact region 105.

The opening 111c is preferably smaller than the p⁺-type contact region 105 as viewed from above the silicon carbide layer 102. Then, even if the position of the opening 111c is off the calculated value due to a misalignment in the mask alignment, etc., the opening 111c can be more reliably disposed so as to overlap the p⁺-type contact region 105. Therefore, substantially the entirety of the lower surface of the source electrode 109 formed in the opening 111c can be more easily brought into contact with the p⁺-type contact region 105.

As described above, in the present embodiment, a portion of the n⁺-type source region 104 that is located in the opening 111c is silicified across its thickness direction to become the source electrode 109. Therefore, as shown in the figures, the n⁺-type source region 104 is in contact only with the side wall of the source electrode 109. The p⁺-type contact region 105 is in contact at least with the lower surface of the source electrode 109.

In the semiconductor device obtained by the method described above, the lower surface of the n⁺-type source region 104 is in contact with the upper surface of the p⁺-type contact region 105 as shown in the figures. In other words, in the silicon carbide layer 102, the n⁺-type source region 104 and the p⁺-type contact region 105 have an overlap with each other in the depth direction.

Although not shown in the figures, the lower surface of the source electrode 109 may be located below the interface between the p⁺-type contact region 105 and the n⁺-type source region 104. In such a case, not only the lower surface of the source electrode 109, but also the lower portion of the side wall, will be in contact with the p⁺-type contact region 105.

It is not necessary that the entire lower surface of the source electrode 109 is in contact with the p⁺-type contact region 105. For example, a portion of the lower surface of the source electrode 109 may not be in contact with the body region 103. Note however that it is preferred that the entire lower surface of the source electrode 109 is in contact with the p⁺-type contact region 105, in which case it is possible to further reduce the resistance between the source electrode 109 and the p⁺-type contact region 105.

Since an upper connection electrode is to be deposited in the opening 111c in a step to be illustrated later, it is preferred that the depth D of the opening 111c, which is determined by the interlayer insulating film 111, the gate electrode 108, the gate insulating film 107, the channel layer 106 and the source electrode 109, is less than the width W of the opening 111c (D<W).

Then, as shown in FIG. 4(d), a portion of the metal layer 109′ that has not been reacted with silicon carbide is removed. Since the metal layer 109′ and the interlayer insulating film 111 have a low reactivity, the metal layer 109′ on the interlayer insulating film 111 can be selectively removed by wet etching using a mixed solution of phosphoric acid, nitric acid, acetic acid, and water. At this point, since the source electrode 109 has already turned into an Ni silicide, it remains through the wet etching.

Next, the drain electrode 110 is formed on a surface (reverse surface) of the substrate 101 opposite to the surface on which the silicon carbide layer 102 is formed. Specifically, first, a metal layer formed by Ti or Ni, for example, is deposited on the reverse surface side of the substrate 101. Next, it is subjected to a heat treatment at a temperature of about 800 to 1000° C., for example, so as to react the metal layer and the substrate 101 with each other. Thus, the drain electrode 110 is obtained, which is in ohmic contact with the reverse surface of the substrate 101.

Then, as shown in FIG. 4(e), the upper connection electrode 112 is deposited on the interlayer insulating film 111 and in the opening 111c. The upper connection electrode 112 is electrically connected to the source electrode 109 in the opening 111c. Al, or the like, for example, is used as the material of the upper connection electrode 112. Another conductive layer may be formed between the upper connection electrode 112 and the source electrode 109 for the purpose of, for example, improving the adhesion therebetween.

Moreover, the reverse surface connection electrode 113 is deposited on the drain electrode 110 as necessary. The reverse surface connection electrode 113 is formed so as to enhance the adhesion with a solder material used for the fixing onto a conductive base (e.g., a leadframe) used for packaging the semiconductor device. For example, the uppermost surface of the reverse surface connection electrode 113 is Ag. The reverse surface connection electrode 113 may be formed by depositing a Ti film, an Ni film and an Ag film, in this order, on the drain electrode 110, or may be formed by a different combination of metal films. The metal of the uppermost surface of the reverse surface connection electrode 113 is appropriately selected depending on the solder material used. The semiconductor device shown in FIG. 1 is obtained as described above.

While the width of the source electrode 109 is shown in FIG. 4(c) to be generally equal to the width W of the opening 111c, the width of the source electrode 109 may be greater than the width W of the opening 111c. This is because the metal of the metal layer 109′ not only diffuses in the downward direction through the channel layer 106, the source region 104 and the contact region 105, but may also diffuse in the lateral direction. In such a case, the difference between the width of the source electrode 109 and the width W of the opening 111c is 200 nm or less, for example. If the diffusion of Ni in the lateral direction is very small, these widths are generally equal to each other as shown in FIG. 4(c).

With the method described above, the thickness of the source electrode 109 can be controlled by adjusting the thickness of the metal layer 109′ deposited in FIG. 4(b) as described above. In the present embodiment, the thickness of the metal layer 109′ is preferably set so that the source electrode 109 has a thickness of 100 nm or more and 500 nm or less, for example.

If the thickness of the source electrode 109 is 100 nm or more, it is possible to ensure a sufficient contact area between the source electrode 109 and the n⁺-type source region 104, and it is therefore possible to suppress the increase in the ON resistance.

As long as the source electrode 109 is disposed so that the lower end thereof does not penetrate through the p⁺-type contact region 105, there is no particular limitation on the upper limit value of the thickness of the source electrode 109. Although the metal layer 109′ needs to be formed thick so as to obtain a thick source electrode 109, detachment of the metal layer 109′ will be likely to occur on the interlayer insulating film 111 if the metal layer 109′ is excessively thick. Therefore, the thickness of the metal layer 109′ is preferably set so that the source electrode 109 will be 1 μm or less (thickness of the metal layer 109′: 0.5 μm or less, for example).

In order to ensure a sufficient contact area between the side wall of the source electrode 109 and the n⁺-type source region 104, the thickness of the n⁺-type source region 104 is preferably 100 nm or more. The upper limit value of the thickness of the n⁺-type source region 104 is preferably 1000 nm or less, for example, though it depends on the thickness of the body region 103.

While the p-type body region 103, the n⁺-type source region 104 and the p⁺-type contact region 105 are formed using the mask layers 201 to 203 in the method described above, there is no particular limitation on the order in which the impurity ion implanted layers are formed.

Although the p-type body region 103, the source region 104 and the p⁺-type contact region 105 are represented by rectangular shapes in FIGS. 1(b), 3 and 4, it is difficult to clearly define the boundaries between the ion implanted regions because these regions are formed by ion implantation. The reason will now be described with reference to the drawings.

FIGS. 5 to 7 are graphs showing examples of depth-direction impurity concentration profiles of the ion implanted layers 103′, 104′ and 105′ (FIG. 3(d)). These ion implanted layers are formed under such conditions (the implantation energy and the dose) as shown in Table 1, for example.

TABLE 1

| | Energy (KeV) | Dose (cm⁻²) |
|---|---|---|
| Ion implanted layer | 700 | 1.0 × 10¹⁴ |
| 103′ to be p-type | 350 | 6.0 × 10¹³ |
| well region | 150 | 2.5 × 10¹³ |
| (Species: Al) | 70 | 1.2 × 10¹³ |
| | 30 | 6.0 × 10¹² |
| Ion implanted layer | 90 | 4.5 × 10¹⁴ |
| 104′ to be n-type | 60 | 2.0 × 10¹⁴ |
| source region | 30 | 1.7 × 10¹⁴ |
| (Species: N) | | |
| Ion implanted layer | 350 | 1.4 × 10¹⁵ |
| 105′ to be p⁺-type | | |
| contact region | | |
| (Species: Al) | | |

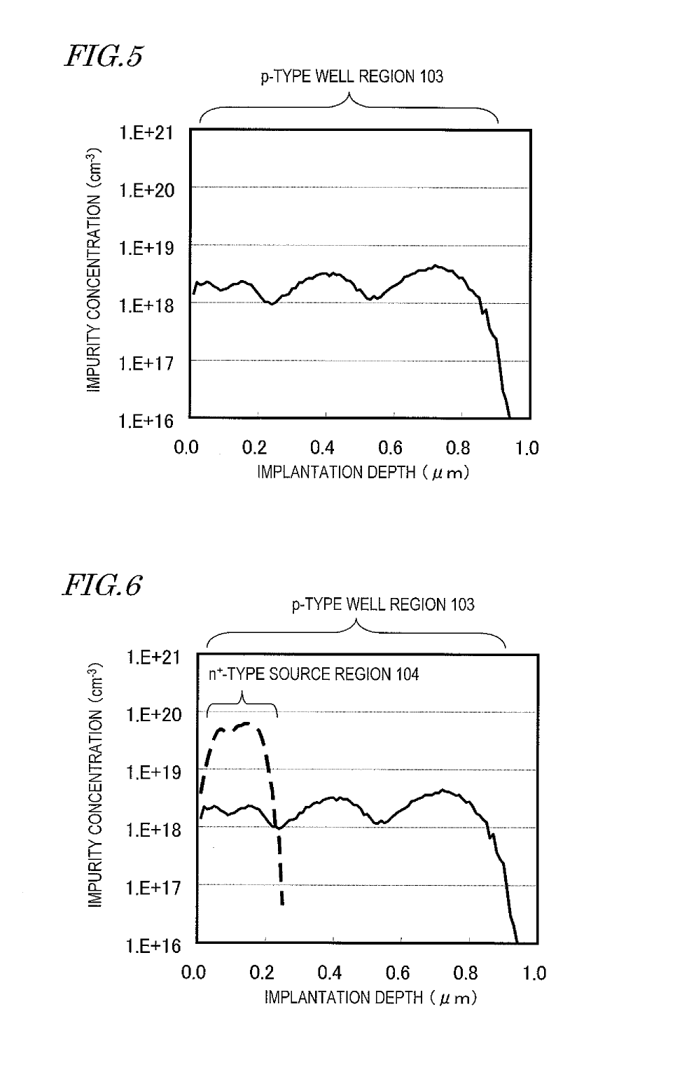

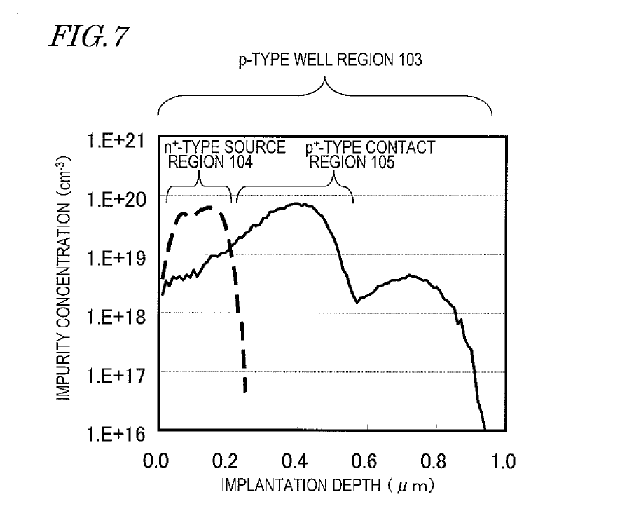

FIG. 5 shows a depth-direction concentration profile of the p-type body region 103 across a cross section along line A-A′ of the unit cell 100 shown in FIG. 3(d). FIG. 6 shows a depth-direction concentration profile of the source region 104 across a cross section along line B-B′ and that of the p-type body region 103, laid on each other. FIG. 7 shows a depth-direction concentration profile of the source region 104 across a cross section along line C-C′ and that of the sum of the p-type body region 103 and the p⁺-type contact region 105, laid on each other. In FIGS. 5 to 7, each dotted line denotes a nitrogen (N) profile, and each solid line denotes an aluminum (Al) profile. In the present specification, a region where the Al concentration is 1×10¹⁹ cm⁻³ or more, for example, in FIG. 7 is represented by a rectangular shape as the p⁺-type conductive region 105. Similarly, a region where the N concentration is 1×10¹⁹ cm⁻³ or more, for example, is represented by a rectangular shape as the n⁺-type source region 104.

Patent Document No. 2 discloses a trench-type field effect transistor, in which a channel layer is formed on a region of the silicon carbide layer where no groove is present for the purpose of avoiding formation of the channel layer on the side wall of the trench (groove). Patent Document No. 2 also discloses a method in which a source region is formed in a portion of a channel layer, after which a groove is provided passing through the source region and then an electrode is formed in the groove. Specifically, first, a silicon carbide layer is formed on a substrate, and a channel layer is formed thereon. Next, a portion of the channel layer is subjected to ion implantation, thereby forming the source region, and a groove is provided passing through the source region. Next, the inside of the groove is subjected to ion implantation, thereby forming a body region. Then, a gate insulating film and a gate electrode are formed on the channel layer. Then, an electrode in contact with the source region and the body region is formed inside the groove. The electrode obtained by this method is also in contact with the source region only on the side wall thereof.

With the method of Patent Document No. 2, however, no p⁺-type contact region is formed in the body region, and no reference is made as to the shape and the size of the p⁺-type contact region. There is also another problem that since the source region is formed in the channel layer, the thickness of the channel layer and that of the n⁺-type source region cannot be controlled based on their respective purposes.

In contrast, in the present embodiment, the contact area between the source electrode and the p⁺-type contact region can be significantly increased from that of the conventional technique. It is also possible to form a p⁺-type contact region larger than that of the conventional technique in the p-type body region without increasing the ON resistance. Therefore, the resistance R2 shown in FIG. 16 can be reduced, and it is therefore possible to prevent problems such as the slowing down of the switching speed due to the parasitic bipolar transistor. Moreover, since the channel layer can be made thinner than the n⁺-type source region, it is possible to ensure a contact area between the source region and the source electrode while suppressing the thickness of the semiconductor device.

### Second Embodiment

A second embodiment of the semiconductor device of the present invention will now be described with reference to the drawings. A semiconductor device of the present embodiment is a vertical MISFET using silicon carbide. The semiconductor device of the present embodiment is different from the semiconductor device shown in FIG. 1 in that p⁺-type contact region and the n⁺-type source region 104 are formed using the same mask.

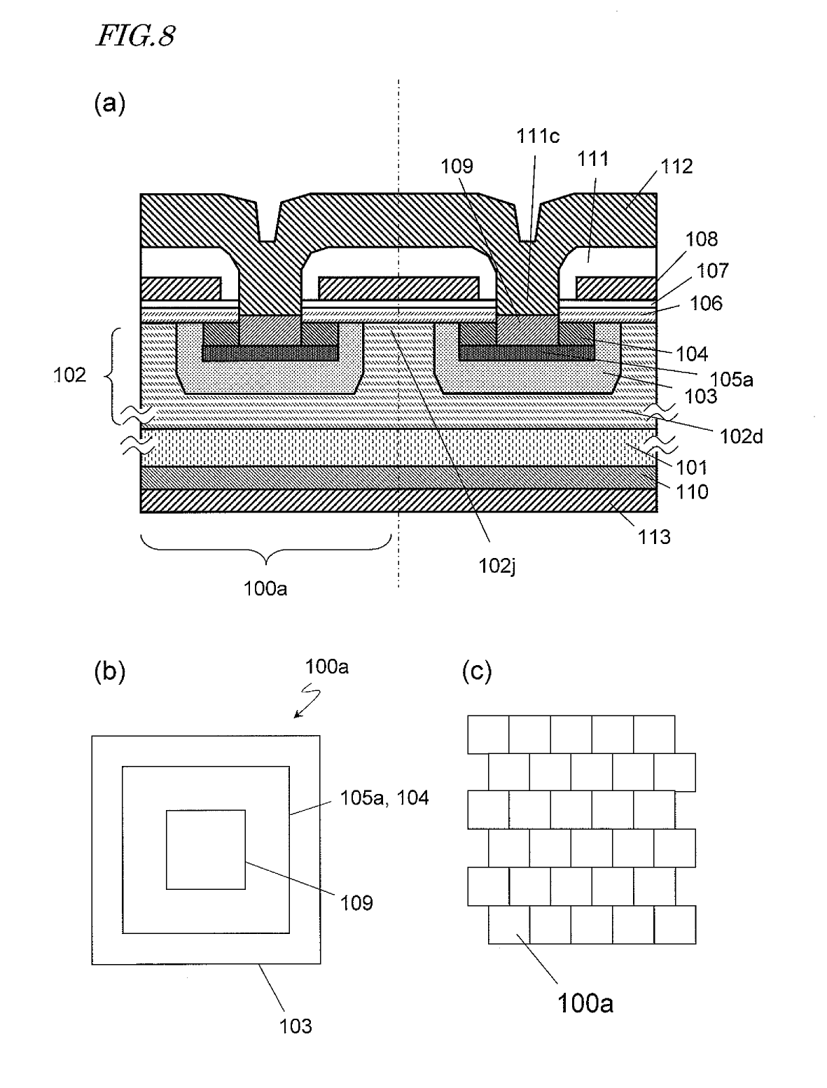

FIG. 8(a) is a schematic cross-sectional view of unit cells of the present embodiment, showing adjacent two unit cells. FIG. 8(b) is a schematic plan view showing the surface of the silicon carbide layer of a unit cell. FIG. 8(c) is a plan view illustrating an arrangement of a plurality of unit cells. For the sake of simplicity, like elements to those of FIG. 1 are denoted by like reference numerals, and will not be further described below. Although a semiconductor device including generally square-shaped unit cells is illustrated herein, a semiconductor device of the present embodiment may have a configuration in which strip-shaped unit cells are arranged as shown in FIG. 2.

An unit cell 100a shown in FIG. 8 includes a p⁺-type contact region 105a containing a p-type impurity at a higher concentration than the p-type body region 103 at a position deeper than the n⁺-type source region 104. The contour of the p⁺-type contact region 105a generally coincides with the contour of the n⁺-type source region 104 as viewed from above the silicon carbide layer 102 (from a direction perpendicular to the substrate 101). Therefore, the area of the p⁺-type contact region 105a is greater than the area of the p⁺-type contact region 105 shown in FIG. 1(a). Otherwise, the configuration of the unit cell 100a is similar to that of the unit cell 100 shown in FIG. 1(a).

The semiconductor device of the present embodiment can be produced by a method described below, for example.

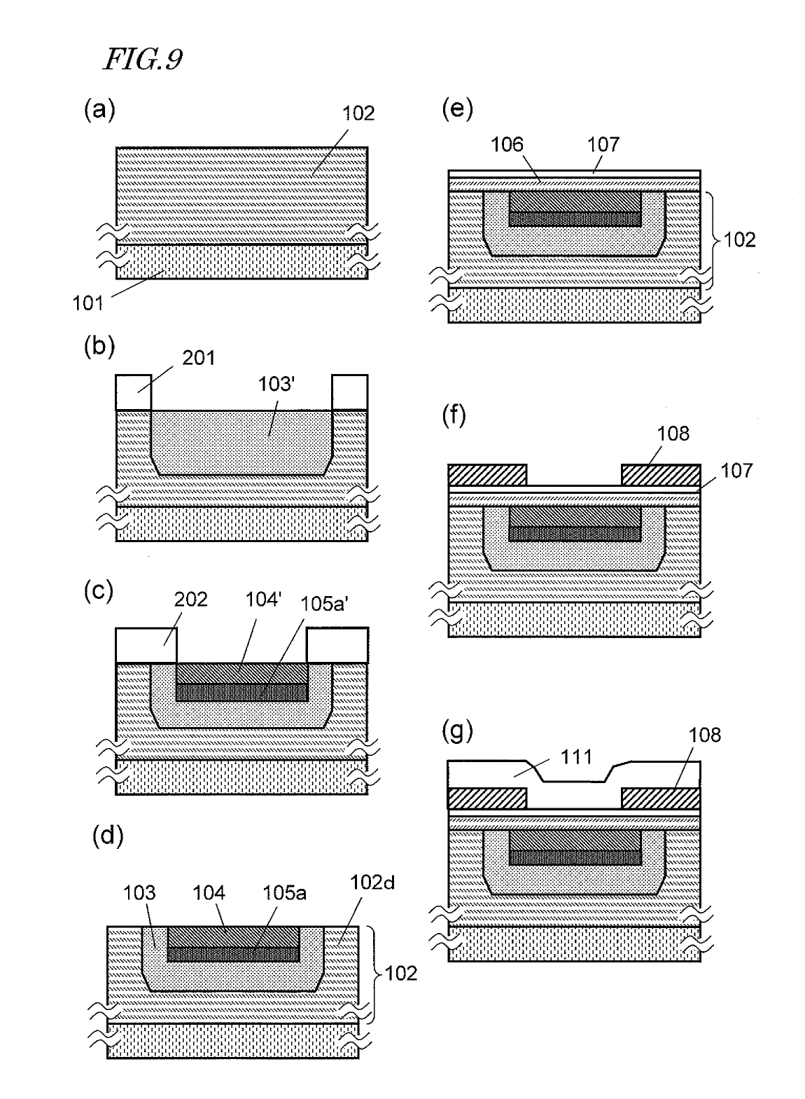

First, as shown in FIG. 9(a), the silicon carbide layer 102 is formed on the substrate 101 formed by silicon carbide. A 4H—SiC substrate similar to the substrate 101 described above with reference to FIG. 3(a) is used as the substrate 101. The silicon carbide layer 102 is formed by a method similar to the method described above with reference to FIG. 3(a).

Next, as shown in FIG. 9(b), a p-type impurity ion (e.g., an Al ion) is implanted into a selected region of the silicon carbide layer 102, thereby forming the first impurity ion implanted layer (thickness: 0.5 μm to 2 μm, for example) 103′. A region of the silicon carbide layer 102 that remains not implanted with an impurity ion becomes the n-type drift region 102d. The method for forming the impurity ion implanted layer 103′ is similar to the method described above with reference to FIG. 3(b).

Then, as shown in FIG. 9(c), the second impurity ion implanted layer (thickness: 0.2 μm to 1 μm, for example) 104′ and a third impurity ion layer (thickness: 0.1 μm to 0.9 μm, for example) 105a′ are formed on the silicon carbide layer 102 using the same mask layer 202.

Specifically, first, the mask layer 202 with an opening through which a portion of the surface of the first impurity ion implanted layer 103′ is exposed is formed on the silicon carbide layer 102. The mask layer 202 may be formed by a similar method after the previous mask layer 201 is removed. Alternatively, an additional layer may be deposited on the mask layer 201, without removing the mask layer 201, and the entire surface may be subjected to anisotropic etching to form a sidewall on the side wall of the mask layer 201, thereby forming the mask layer 202 formed by the mask layer 201 and the sidewall (self-aligned process). Herein, the shape of the opening in the mask layer 202 is designed so that the surface of the second impurity ion implanted layer 104′ has a square shape (length of each side: 5.6 μm, for example). Next, an n-type impurity ion (e.g., a nitrogen ion or a phosphorus ion) is implanted into the silicon carbide layer 102 from above the mask layer 202. Thus, the second impurity ion implanted layer 104′ is obtained. Then, a p-type impurity ion (e.g., an Al ion) is implanted into the silicon carbide layer 102 from above the mask layer 202. Thus, the third impurity ion implanted layer 105a′ is formed in the silicon carbide layer 102. The substrate temperature during the ion implantation is similar to the substrate temperature during the p-type impurity ion implantation described above with reference to FIG. 3(b). After the ion implantation, the mask layer 202 is removed.

The third impurity ion implanted layer 105a′ is formed under the second impurity ion implanted layer 104′ (at a position deeper than the second impurity ion implanted layer 104′). The second impurity ion implanted layer 104′ and the second impurity ion implanted layer 105′ may have some overlap at the interface therebetween. With this process, since the second impurity ion implanted layer 104′ and the third impurity ion implanted layer 105a′ are formed by using the same mask layer 202, it is possible to simplify the mask layer formation process.

In FIG. 9, the n⁺-type source region 104 and the p⁺-type contact region 105a are formed by using the same mask layer 202 and have the same width (the length in the direction parallel to the substrate surface).

Then, as shown in FIG. 9(d), the first, second and third impurity ion implanted layers 103′, 104′ and 105′ are subjected to an activation anneal at a high temperature of 1500° C. or more, thereby forming the p-type body region 103, the n⁺-type source region 104 and the p⁺-type contact region 105a, respectively. The impurity concentrations of the p-type body region 103 and the n⁺-type source region 104 obtained are determined by the conditions during the ion implantation described above, and are adjusted in the range of 1×10¹⁷ to 1×10¹⁹ cm⁻³ and in the range of 1×10¹⁸ to 1×10²¹ cm⁻³, respectively. The impurity concentration of the p⁺-type contact region 105a is adjusted so that it is higher than the impurity concentration of the p-type body region 103.

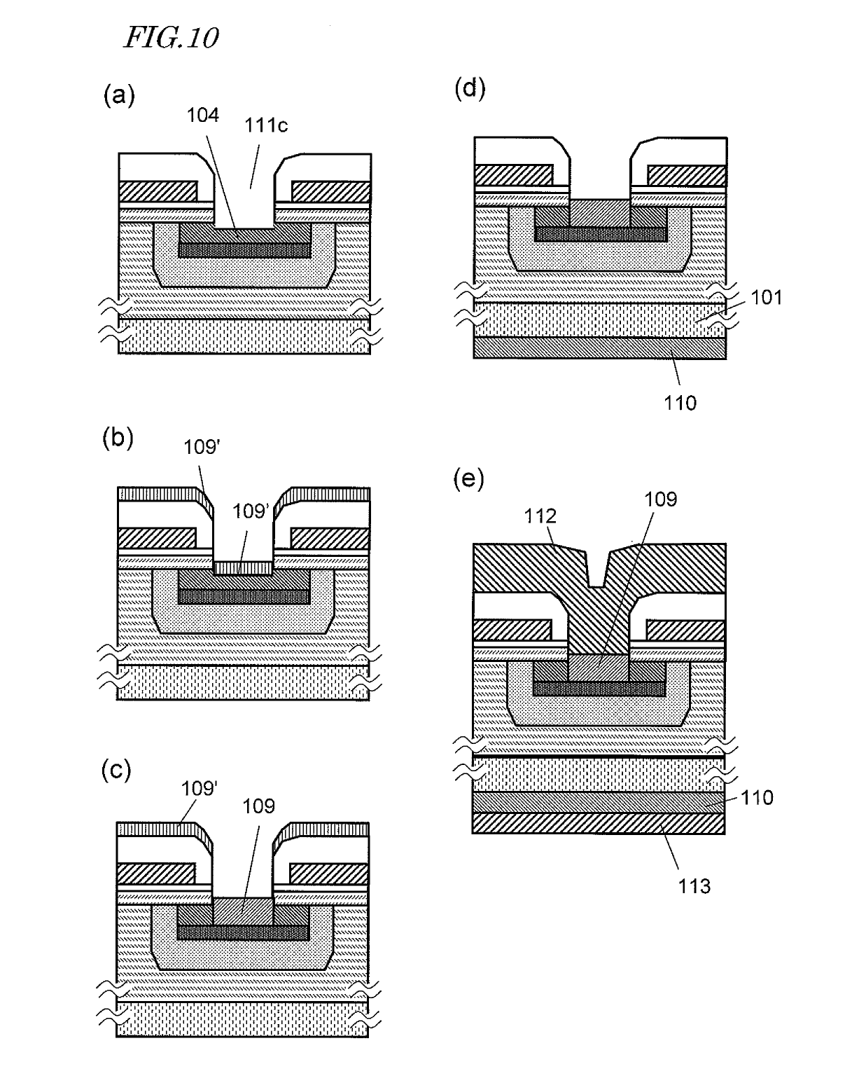

Subsequent processes are shown in FIGS. 9(e) to 9(g) and FIGS. 10(a) to 10(e). These processes are similar to the processes described above with reference to FIGS. 3(f) to 3(h) and FIGS. 4(a) to 4(e), respectively, and will not be further described below.

With the present embodiment, the contact area between the p⁺-type contact region 105a and the source electrode 109 can be made larger than that of the conventional semiconductor device 1000, and it is therefore possible to reduce the contact resistance. Since the p⁺-type contact region 105a can be formed to be even larger than the p⁺-type contact region 105 (FIG. 1) of the first embodiment, and it is therefore possible to more effectively reduce the resistance R2 shown in FIG. 16. For example, where each side of the body region 103 is 6.6 μm on a cross section that is parallel to the principle surface of the SiC substrate 101 and that includes the p⁺-type contact region 105 and the p-type body region 103 in contact with the p⁺-type contact region 105, each side of the p⁺-type contact region 105 has the same length (6 μm, for example) as each side of the source region 104, and therefore the area percentage of the contact region is about 80%.

As a result, it is possible to prevent the parasitic bipolar transistor from being turned ON, and it is therefore possible to suppress the deterioration of the switching characteristic. Since the source electrode 109 is in contact with the n⁺-type source region 104 only on the side wall thereof, it is possible to reduce the size of each unit cell without significantly increasing the ON resistance.

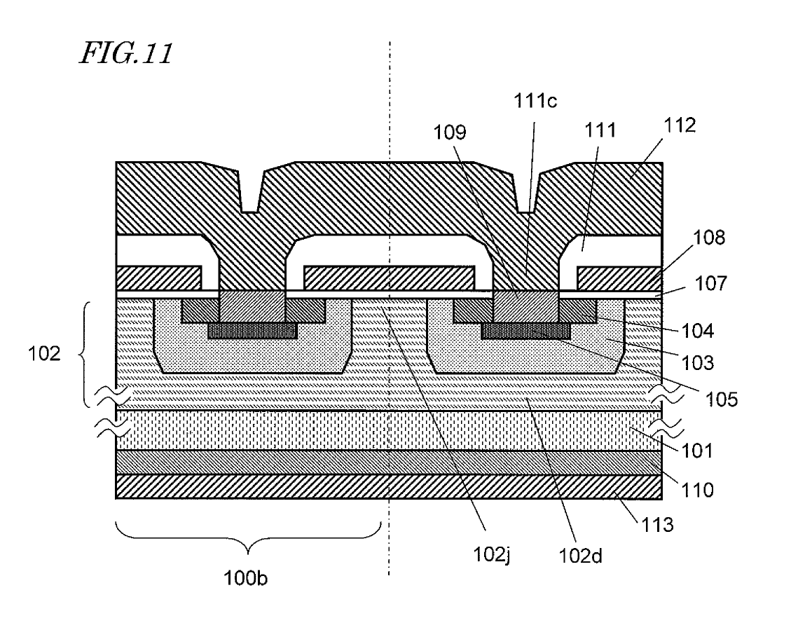

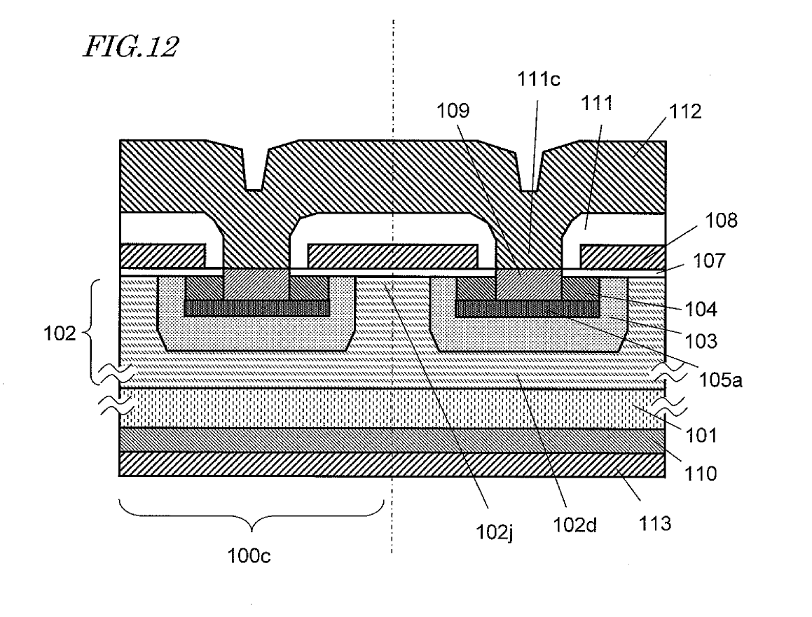

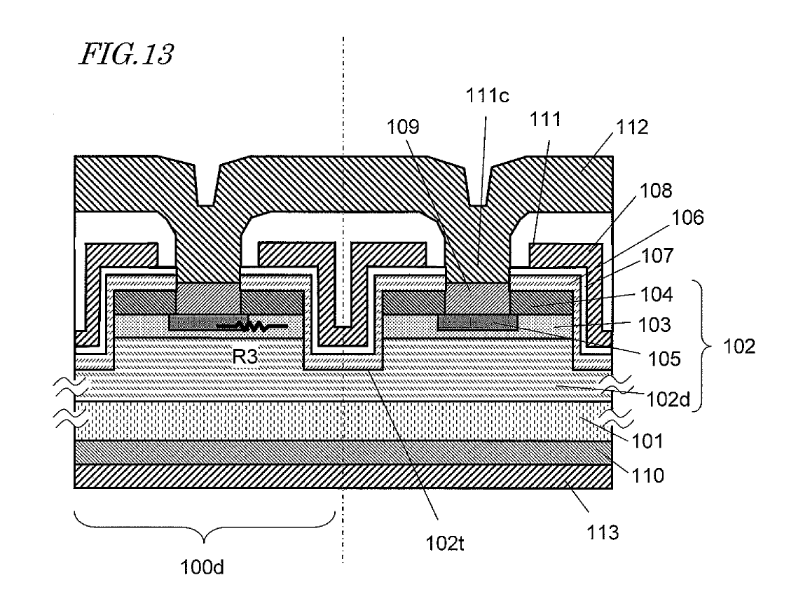

The configuration of the semiconductor device of the present invention is not limited to that shown in FIGS. 1 and 8. While the semiconductor devices shown in FIGS. 1 and 8 each have an accumulation channel structure in which the channel layer 106 is provided between the silicon carbide layer 102 and the gate insulating film 107, the semiconductor device of the present invention does not need to have the channel layer 106. A configuration of a semiconductor device that does not have the channel layer 106 is shown in FIGS. 11 and 12. In a semiconductor device that does not have the channel layer 106, a channel can be formed by partially inverting the conductivity type of the p-type body region 103 under the gate electrode 108 by way of a voltage applied to the gate electrode 108 (inverted channel structure).

While the semiconductor devices of the embodiments described above are so-called “double-implanted” MISFETs (DiMISFETs, DMISFETs), they may be trench-type MISFETs (UMISFETs).

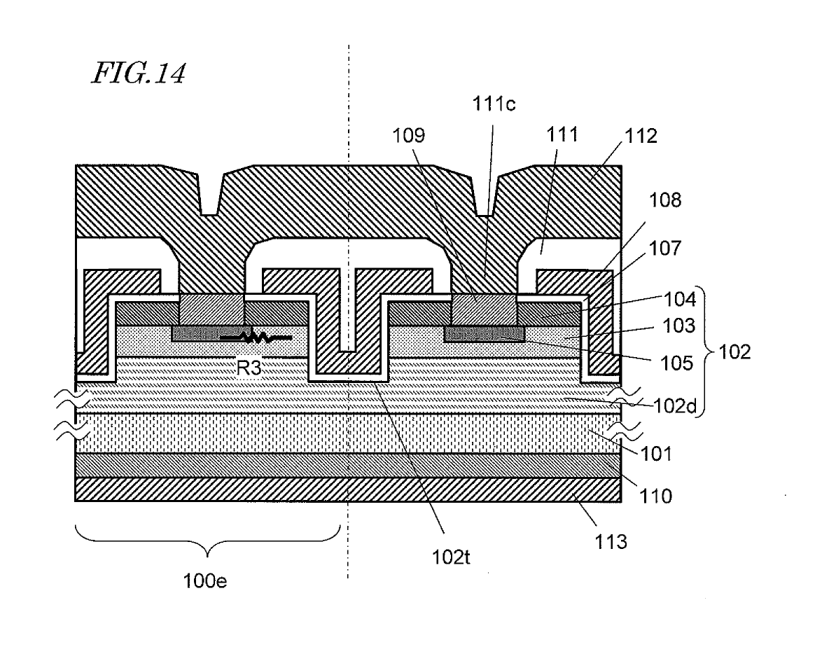

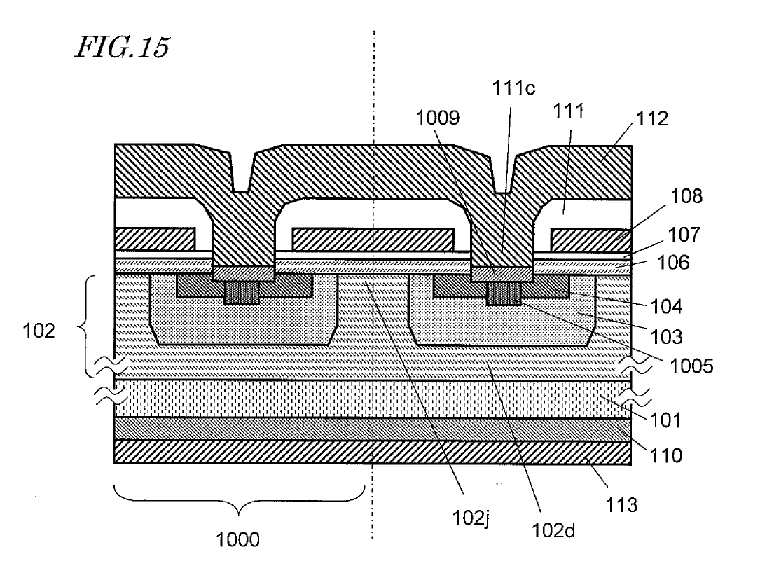

FIGS. 13 and 14 are schematic cross-sectional views of semiconductor devices according to other embodiments of the present invention, wherein FIG. 13 shows a unit cell of a UMISFET of an accumulation channel structure, and FIG. 14 shows a unit cell of a UMISFET of an inverted channel structure. For the sake of simplicity, like elements to those of FIGS. 1 and 8 are denoted by like reference numerals, and will not be further described below.

In an unit cell 100d shown in FIG. 13, the body region 103 is formed under the n⁺-type source region 104 in contact with the n⁺-type source region 104, and is not surrounding the n⁺-type source region 104. The p⁺-type contact region 105 is disposed in the body region 103, and is electrically connected to the body region 103. The drift region 102d is disposed between the body region 103 and the substrate 101. At least a portion of the n⁺-type source region 104 overlaps the p⁺-type contact region 105 as viewed from above the substrate 101.

A trench 102t passing through the n⁺-type source region 104 and the body region 103 to reach the drift region 102d is formed in the silicon carbide layer 102. In the trench 102t, the channel layer 106 is formed so as to cover the side wall of the n⁺-type source region 104 and the side wall of the body region 103. In the trench 102t, the gate electrode 108 is provided on the channel layer 106 with the gate insulating film 107 interposed therebetween. Otherwise, the configuration is similar to that shown in FIG. 1.

Also in the present embodiment, the width of the p⁺-type contact region 105 is preferably greater than the width of the source electrode 109 on any cross section perpendicular to the principle surface of the substrate 101, whereby the entire lower surface of the source electrode 109 can be brought into contact with the p⁺-type contact region 105. Note however that the width of the p⁺-type contact region 105 is set to be smaller than the width of the body region 103 on any cross section perpendicular to the principle surface of the substrate 101 so that the p⁺-type contact region 105 is disposed in the body region 103. Therefore, in the present embodiment, the width of the p⁺-type contact region 105 is set to be smaller than the width of the n⁺-type source region 104.

An unit cell 100e shown in FIG. 14 has a similar configuration to that shown in FIG. 13 except that the channel layer 106 is absent.

Also with the semiconductor devices shown in FIGS. 13 and 14, the contact area between the p⁺-type contact region 105 and the source electrode 109 can be made larger as compared with conventional techniques, without substantially increasing the resistance of the source electrode 109 and the n⁺-type source region 104, and it is therefore possible to reduce the contact resistance. Since the p⁺-type contact region 105 can be made larger, it is possible to further reduce the resistance R3, which is determined by the p-type body region 103 and the p⁺-type contact region 105. Therefore, it is possible to prevent the parasitic bipolar transistor from being turned ON, and it is therefore possible to suppress the deterioration of the switching characteristic. Moreover, since the n⁺-type source region 104 is in contact only with the side wall of the source electrode 109, it is possible to reduce the size of the unit cell and to increase the density with which unit cells are loaded.

While the source electrode 109 formed by an Ni silicide is formed by reacting Ni and silicon carbide with each other in the embodiments described above, a different metal material (e.g., Ti and Co) capable of forming an ohmic junction with the silicon carbide layer, instead of Ni, may be reacted with silicon carbide, thereby forming a source electrode formed by a different metal silicide.

While a 4H—SiC substrate is used as the substrate 101 in the embodiments described above, crystal planes (the (11-20) plane, the (1-100) plane, etc.) or other polytype SiC substrates (e.g., 6H—SiC, 15R—SiC, etc.) may be used. Where a 4H—SiC substrate is used, the silicon carbide layer 102 and the drain electrode 110 may be formed on the Si surface side and on the C surface side, respectively, or the silicon carbide layer 102 and the drain electrode 110 may be formed on the C surface side and on the Si surface side, respectively.

The semiconductor devices of the embodiments described above are all n-channel semiconductor devices, they may be p-channel semiconductor devices. In a p-channel semiconductor device (MISFET), the conductivity type of the SiC substrate 101, the drift region 102j, the source region 104 and the channel layer 106 is the p type, and that of the body region 103 and the contact regions 105 and 105a is the n type.

Moreover, while the MISFET is manufactured using the SiC substrate 101 of the same conductivity type as the silicon carbide layer 102 in the embodiments described above, an insulated gate bipolar transistor (IGBT) can be manufactured using an SiC substrate whose conductivity type is different from that of the silicon carbide layer 102. Also when an IGBT is manufactured, advantageous effects similar to those of the embodiments described above can be obtained by forming the source electrode, the source region and the contact region so that the side wall of the source electrode (referred to also as an emitter.) is in contact with the source region (referred to also as an emitter region.), the lower surface of the source electrode is in contact with the contact region, and the lower surface of the source electrode is not in contact with the source region.

### INDUSTRIAL APPLICABILITY

The present invention is widely applicable to semiconductor devices using silicon carbide and apparatuses using the same. The present invention is particularly suitable for accumulation channel-type or inverted channel-type MISFETs.

If the present invention is applied to a MISFET, it is possible to prevent the switching speed of the MISFET from being slowed down as the parasitic bipolar transistor is turned ON instantaneously, without increasing the ON resistance. It is also possible to increase the density with which unit cells are loaded. Moreover, with the present invention, it is possible to manufacture such semiconductor devices as described above without complicating the manufacturing processes.

### REFERENCE SIGNS LIST

101 Substrate
102 Silicon carbide layer
103 P-type body region
104 N⁺-type source region
105, 105a P⁺-type contact region
106 Channel layer
107 Gate insulating film
108 Gate electrode
109 Source electrode
110 Drain electrode
111 Interlayer insulating film
112 Upper connection electrode
113 Reverse surface connection electrode
100, 100a, 100b, 100c, 100d, 100e Semiconductor device unit cell

1. A semiconductor device comprising:
a substrate;
a silicon carbide layer disposed on the substrate;
a source region of a first conductivity type disposed in the silicon carbide layer;
a body region of a second conductivity type disposed at a position in contact with the source region in the silicon carbide layer;
a contact region of the second conductivity type disposed in the body region and electrically connected to the body region;
a drift region of the first conductivity type disposed in a region of the silicon carbide layer excluding the source region, the body region and the contact region; and
a source electrode in ohmic contact with the source region and the contact region, wherein:
the source electrode is formed by a metal silicide layer;
a thickness of the source electrode is greater than a thickness of the source region;
a side wall of the source electrode is in contact with the source region;
a lower surface of the source electrode is in contact with the contact region and is not in contact with the source region; and
at least a portion of the source region overlaps the contact region as viewed from a direction perpendicular to a principle surface of the substrate.

2. (canceled)

3. The semiconductor device according to claim 1, wherein the lower surface of the source electrode is located within the contact region as viewed from the direction perpendicular to the principle surface of the substrate.

4. The semiconductor device according to claim 1, wherein substantially an entirety of the lower surface of the source electrode is in contact with the contact region.

5. (canceled)

6. The semiconductor device according to claim 1, wherein at least a portion of the contact region is disposed at a position deeper than a lower end of the source region in the silicon carbide layer.

7. The semiconductor device according to claim 6, wherein a contour of the contact region generally coincides with a contour of the source region as viewed from the direction perpendicular to the principle surface of the substrate.

8. The semiconductor device according to claim 1, wherein the body region is formed in a surface region of the silicon carbide layer so as to surround the source region, the semiconductor device further comprising:
a gate insulating film covering a portion of the silicon carbide layer; and
a gate electrode insulated from the silicon carbide layer by the gate insulating film,
wherein the gate electrode covers at least a portion of the source region.

9. The semiconductor device according to claim 1, wherein the body region is disposed under the source region in contact with the source region, the semiconductor device further comprising:
a trench passing through the source region and the body region to reach the drift region;
a gate insulating film disposed in the trench so as to cover a side surface of the body region;
a gate electrode insulated from the silicon carbide layer by the gate insulating film;
an upper electrode electrically connected to the source electrode; and
a drain electrode provided on a reverse surface of the substrate.

10. The semiconductor device according to claim 8, further comprising a channel layer of the first conductivity type disposed between the gate insulating film and the silicon carbide layer, wherein the channel layer is in contact with the source region.

11. The semiconductor device according to claim 1, wherein:
the source region contains an impurity element imparting the first conductivity type; and
the source electrode contains carbon and the same element as the impurity element.

12. The semiconductor device according to claim 1, wherein on a cross section that is parallel to the principle surface of the substrate and that includes the contact region and the body region, a percentage of area of the contact region with respect to the body region is 20% or more and 80% or less.

13. A method for manufacturing a semiconductor device comprising:
a silicon carbide layer formation step of forming a silicon carbide layer including a source region of a first conductivity type, a body region of a second conductivity type in contact with the source region, a contact region of the second conductivity type disposed in the body region and electrically connected to the body region, and a drift region of the first conductivity type disposed in a region of the silicon carbide layer excluding the body region, the source region and the contact region;
a step of forming a gate insulating film and a gate electrode on the silicon carbide layer; and
a source electrode formation step of forming a source electrode formed by a metal silicide in ohmic contact with the source region and the contact region, wherein a side wall of the source electrode is in contact with the source region, and a lower surface of the source electrode is in contact with the contact region and is not in contact with the source region,
wherein after the source electrode is formed, at least a portion of the source region overlaps the contact region as viewed from a direction perpendicular to a principle surface of the substrate.

14. The method for manufacturing a semiconductor device according to claim 13, wherein the source electrode formation step comprises the steps of:
(a1) etching a portion of the silicon carbide layer so as to expose a side wall of the source region;
(a2) forming a metal layer so as to be in contact with the exposed side wall of the source region; and
(a3) performing a heat treatment so as to diffuse a metal contained in the metal layer into the source region and the contact region and react the metal and silicon carbide with each other, thereby forming the source electrode.

15. The method for manufacturing a semiconductor device according to claim 13, wherein the source electrode formation step comprises the steps of:
(b1) forming a metal layer on a portion of the source region; and
(b2) performing a heat treatment so as to diffuse a metal contained in the metal layer into the source region and the contact region and react the metal and silicon carbide with each other, thereby forming the source electrode.

16. The method for manufacturing a semiconductor device according to claim 15, further comprising the step of:
forming, on the silicon carbide layer, a channel layer that is in contact with the source region and is formed by silicon carbide of the first conductivity type, prior to the
step of forming the gate insulating film and the gate electrode,
wherein in the step of forming the gate insulating film and the gate electrode, the gate insulating film and the gate electrode are formed on the channel layer.

17. The method for manufacturing a semiconductor device according to claim 13, wherein the silicon carbide layer formation step comprises the steps of:
preparing a substrate with a silicon carbide layer of the first conductivity type formed on a surface thereof;
implanting an impurity of the second conductivity type into the silicon carbide layer of the first conductivity type using a first implantation mask, thereby forming the body region;
implanting an impurity of the first conductivity type into the silicon carbide layer of the first conductivity type using a second implantation mask, thereby forming the source region; and
implanting an impurity of the second conductivity type into the body region using a third implantation mask, thereby forming the contact region.

18. The method for manufacturing a semiconductor device according to claim 17, wherein the third implantation mask is the same as the second implantation mask.

19. The semiconductor device according to claim 1, wherein the source electrode passes through the source region to be in contact with the contact region.

20. The semiconductor device according to claim 8, further comprising an upper electrode electrically connected to the source electrode, and a drain electrode provided on a reverse surface of the substrate.

21. The method for manufacturing a semiconductor device according to claim 16, wherein:
the step (b1) is a step of forming the metal layer on the channel layer; and
in the step (b2), the metal is diffused into the channel layer, the source region and the contact region so as to react the metal and silicon carbide with each other.

22. The method for manufacturing a semiconductor device according to claim 16, wherein the step of forming the channel layer is performed after the silicon carbide layer formation step.

23. The semiconductor device according to claim 9, wherein the contact region is not in contact with a side wall of the trench.

24. The semiconductor device according to claim 10, wherein a side wall of the source electrode is in contact with the channel layer.
